(19) United States
(12) Patent Application Publication
(10) Pub. No.: US 2025/0056936 A1
(43) Pub. Date: Feb. 13, 2025

(54) SIDE EMITTING LED PACKAGE WITH BEVEL LIGHT EMITTING SURFACE

(71) Applicant: DOMINANT Opto Technologies Sdn Bhd., Melaka (MY)

(72) Inventors: Low Tek Beng, Melaka (MY); Tan Eng Wah, Melaka (MY); Lim Chee Sheng, Melaka (MY)

(21) Appl. No.: 18/929,396

(22) Filed: Oct. 28, 2024

Related U.S. Application Data
(63) Continuation-in-part of application No. 17/651,365, filed on Feb. 16, 2022, now Pat. No. 12,159,962.

(30) Foreign Application Priority Data
Dec. 16, 2021 (MY) PI 2021007539

(51) Int. Cl. H01L 33/50; H01L 25/16; H01L 33/32; H01L 33/60

(52) U.S. Cl. CPC H01L 33/505; H01L 33/502; H01L 33/60; H01L 25/167; H01L 33/32

(57) ABSTRACT

The described technology includes a side emitting light emitting diode (LED) package with a bevel light emitting surface, and LED displays including the disclosed LED packages. The LED package can include a substrate, an LED chip, a light converter, and a cap. The LED chip can be positioned over the substrate, and the light converter can comprise a transparent material also positioned over the substrate and surrounding the LED chip. The cap can be positioned over the light converter to inhibit emission of light perpendicular to the surface of the substrate. The outer side surfaces of the light converter can be inclined, so that the light converter is wider at the base than at the top. The incline angle can be selected to collimate emitted light. LED displays including the disclosed LED packages can include multiple LED packages affixed to a printed circuit board (PCB) along with other components.

### RELATED APPLICATION

The subject patent application is a continuation in part application that claims priority under 35 U.S.C. § 120 to U.S. patent application Ser. No. 17/651,365, filed Feb. 16, 2022, and entitled “SIDE EMITTING LED PACKAGE WITH BEVEL LIGHT EMITTING SURFACE,” which patent application claims priority under 35 U.S.C. § 119 to Malaysia Pat. App. No. PI 2021007539, filed Dec. 16, 2021, and entitled “SIDE EMITTING LED PACKAGE WITH BEVEL LIGHT EMITTING SURFACE,” the entireties of which applications are hereby incorporated by reference herein.

### TECHNICAL FIELD

The subject application generally relates to Light Emitting Diode (LED) structures and displays incorporating LEDs.

### BACKGROUND

LED displays generally include many small LED elements affixed to printed circuit boards (PCBs), and one or more additional layers positioned over the LED elements. The LED elements can be activated via the PCBs to generate light for the LED display, and the light generated by the LED elements can optionally be manipulated via the additional layers.

One consideration in the design of LED elements for use in LED displays is display brightness. Displays that can achieve greater brightness are generally preferable, particularly in certain environments such as vehicles. Displays within vehicles are often in conditions such as direct sunlight or high ambient light, which can reduce the effective visibility of such displays.

Another consideration in the design of LED elements for use in LED displays is avoiding speckling and spotting effects in LED displays. For example, designs in which individual LED elements concentrate light directly at the additional layers of an LED display can lead to unwanted bright spots on the LED display, with each bright spot being produced by an individual underlying LED element. To avoid bright spots, the light generated by LED elements should be sufficiently uniform and diffuse before it traverses the additional layers.

The above-described background is merely intended to provide a contextual overview of some current issues and is not intended to be exhaustive. Other contextual information may become further apparent upon review of the following detailed description.

### BRIEF DESCRIPTION OF THE DRAWINGS

The technology described herein is illustrated by way of example and not limited in the accompanying figures in which like reference numerals indicate similar elements and in which:

FIG. 1 illustrates an example side emitting LED package, in accordance with one or more embodiments described herein.

FIG. 2 illustrates another example side emitting LED package and various example angles and dimensions thereof, in accordance with one or more embodiments described herein.

FIG. 3 illustrates example light emission from a side emitting LED package, in accordance with one or more embodiments described herein.

FIG. 4 illustrates another example side emitting LED package, in accordance with one or more embodiments described herein.

FIG. 5 illustrates an example LED display including side emitting LED packages, in accordance with one or more embodiments described herein.

FIG. 6 illustrates example light emission from the LED display of FIG. 5, in accordance with one or more embodiments described herein.

FIG. 7 is a three-dimensional view of another example side emitting LED package, in accordance with one or more embodiments described herein.

FIG. 8 is a flow diagram of an example method to manufacture a side emitting LED package, in accordance with one or more embodiments described herein.

FIG. 9 illustrates an example side emitting LED package, in accordance with one or more embodiments described herein.

FIG. 10 illustrates another example side emitting LED package, in accordance with one or more further embodiments described herein.

FIG. 11 illustrates example light emission from a side emitting LED package, in accordance with one or more embodiments described herein.

FIG. 12 further illustrates example light emission from a side emitting LED package, in accordance with one or more other embodiments described herein.

FIG. 13 illustrates another example LED display including side emitting LED packages, in accordance with one or more embodiments described herein.

FIG. 14 illustrates another example side emitting LED package, in accordance with one or more further embodiments described herein.

FIG. 15 illustrates another example side emitting LED package, in accordance with one or more embodiments described herein.

FIG. 16 illustrates still another example side emitting LED package, in accordance with one or more embodiments described herein.

FIG. 17 illustrates an example side emitting LED package, in accordance with one or more further embodiments described herein.

### DETAILED DESCRIPTION

One or more embodiments are now described with reference to the drawings, wherein like reference numerals are used to refer to like elements throughout. In the following description, for purposes of explanation, numerous specific details are set forth in order to provide a thorough understanding of the various embodiments. It may be evident, however, that the various embodiments can be practiced without these specific details.

Example embodiments are directed to a side emitting LED package with a bevel light emitting surface, and LED displays including the disclosed LED packages. A side emitting LED package with a bevel light emitting surface can include a substrate, an LED chip, a light converter, and a cap. The LED chip can be positioned over the substrate, and the light converter can comprise a substantially transparent material also positioned over the substrate and surrounding the LED chip. The cap can be positioned over the light converter to inhibit emission of light perpendicular to the surface of the substrate. The outer side surfaces of the light converter can be inclined, so that the light converter is wider at the base, adjacent to the substrate, than at the top, adjacent to the cap. The incline angle can be selected to collimate light emitted from the LED package. LED displays including the disclosed LED packages can include multiple of the disclosed LED packages affixed to a printed circuit board (PCB) along with various other components described herein. Further aspects and embodiments of this disclosure are described in detail below.

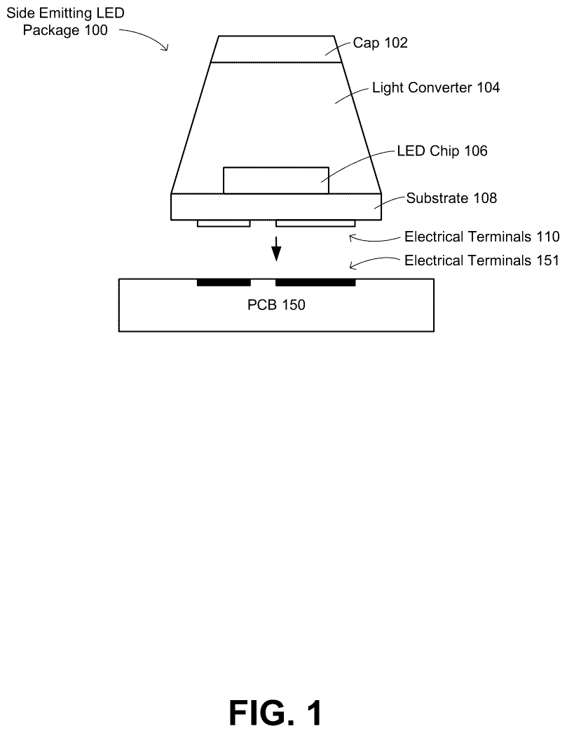

FIG. 1 illustrates an example side emitting LED package, in accordance with one or more embodiments described herein. The example side emitting LED package 100 comprises a cap 102, a light converter 104, an LED chip 106, a substrate 108, and electrical terminals 110. The electrical terminals 110 are configured to couple with electrical terminals 151 of a PCB 150.

When the electrical terminals 110 of the side emitting LED package 100 are coupled with the with electrical terminals 151 of the PCB 150, the side emitting LED package 100 can be operated via the PCB 150. The side emitting LED package 100 can be activated, causing the LED chip 106 to emit light. Light emitted by the LED chip 106 passes through the light converter 104 and the light is emitted from the sides of the light converter 104.

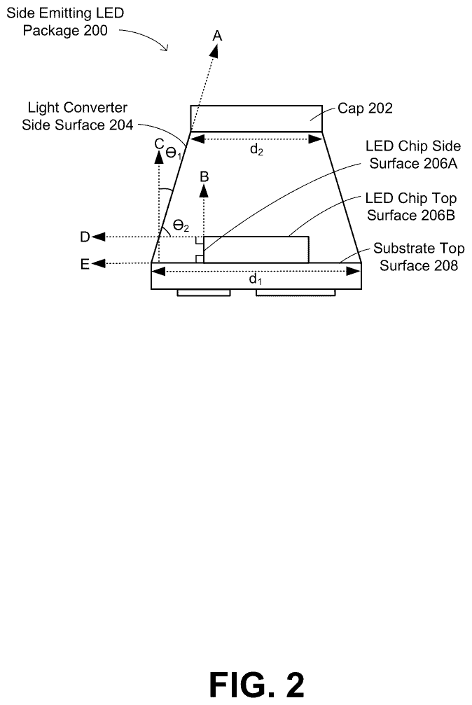

FIG. 2 illustrates another example side emitting LED package and various example angles and dimensions thereof, in accordance with one or more embodiments described herein. The example side emitting LED package 200 comprises a cap 202 which has a different shape than cap 102. Otherwise, the components of the side emitting LED package 200 are similar to those of side emitting LED package 100 illustrated in FIG. 1. In general, numerous potential modifications to the shapes and sizes of the illustrated components, including the cap 202 as well as the light converter 104, LED chip 106, substrate 108, and electrical terminals 110, can be made in accordance with embodiments of this disclosure, and this disclosure is not limited to any particular component shapes or dimensions unless explicitly stated otherwise.

FIG. 2 illustrates a ray A that extends upward from a light converter outer side surface, wherein the ray A is parallel with the light converter outer side surface. FIG. 2 furthermore illustrates a ray B that extends upward from an LED chip side surface, wherein the ray B is parallel with the LED chip side surface. FIG. 2 furthermore illustrates a ray C that is parallel with the ray B, in order to illustrate an inclined angle θ₁. The inclined angle θ₁ also represents the angle at which rays A and B intersect, as can be appreciated. The term “inclined angle” as used herein includes any angle other than 90 degrees (perpendicular) and 0 degrees (flat).

FIG. 2 furthermore illustrates a ray D that extends outward from an LED chip top surface, wherein the ray D is parallel with the LED chip top surface. When the LED chip is rectangular, as in FIG. 2, the rays B and D are perpendicular, as shown. The ray D intersects the ray A at an inclined angle θ₂. FIG. 2 furthermore illustrates a ray E that extends outward from a substrate top surface, wherein the ray E is parallel with the substrate top surface. In FIG. 2, the substrate top surface is parallel to the LED chip top surface and the substrate top surface is perpendicular to the LED chip side surface, and so rays E and D are parallel, rays E and B are perpendicular, and rays D and E both intersect the ray A at a same inclined angle θ₂.

FIG. 2 furthermore illustrates a distance d₁, which can represent a width at the base of the light converter, i.e., the width of the portion of the light converter that is adjacent the substrate. Another distance d₂ can represent a width at the top of the light converter, i.e., the width of the portion of the light converter that is adjacent the cap 202. The distance d₁ and d₂ can be used, e.g., in connection with measuring the perimeter of the light converter adjacent the substrate and the perimeter of the light converter adjacent the cap.

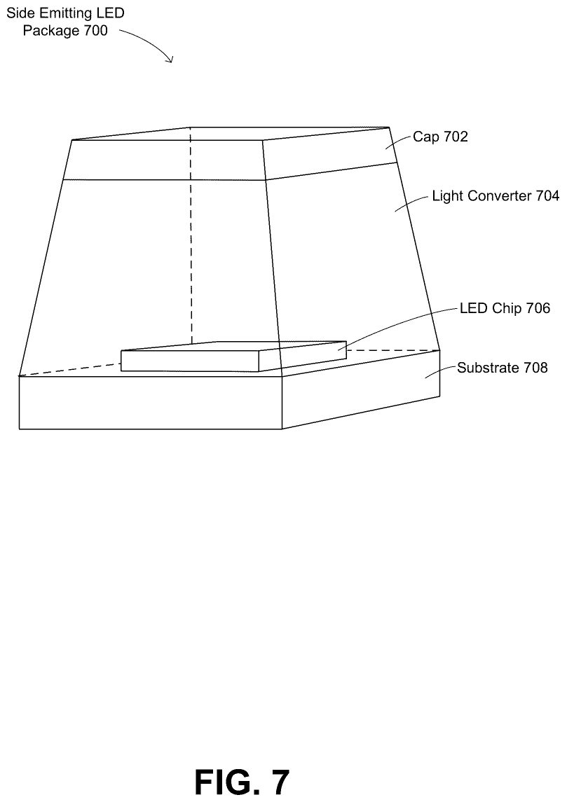

FIGS. 1, 2 and the various other illustrations herein provide side views of three-dimensional components, as can be appreciated. Example three dimensional components of a side emitting LED package are illustrated in FIG. 7. In general, side emitting LED packages according to embodiments of this disclosure can include light converter outer side surface(s) that are at inclined angle(s), as shown. The inclined angle(s) are described herein as inclined with respect to components of the side emitting LED package, such as the LED chip top surface, the substrate top surface, the LED chip side surface, or, e.g., the bottom surface of the cap 202. The inclined angle(s) are also described herein as differences in width or perimeter between the base of the light converter, having width d₁, and the top of the light converter, having width d₂. The inclined angle(s) are furthermore described herein by describing surfaces such as the light converter outer side surface(s), the LED chip top surface, the substrate top surface, and the LED chip side surface as portions of respective planes, while specifying that the respective planes can intersect at inclined angle(s).

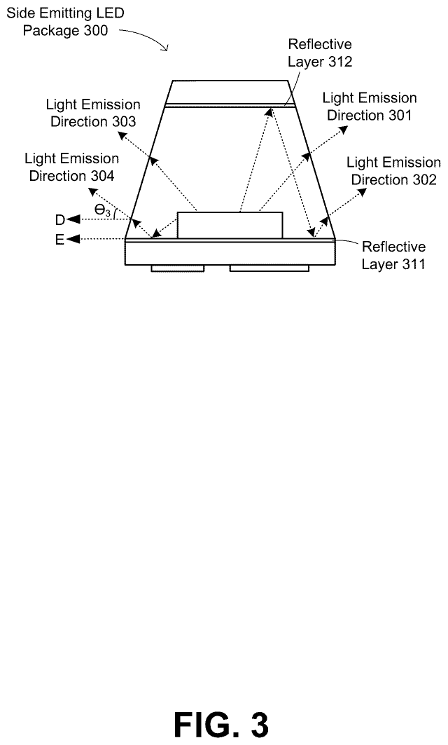

FIG. 3 illustrates example light emission from a side emitting LED package, in accordance with one or more embodiments described herein. FIG. 3 includes an example side emitting LED package 300 having components generally similar to those introduced in FIG. 1. In FIG. 3, the cap includes an example reflective layer 312, and the substrate also includes a reflective layer 311.

Light rays can be emitted by the LED chip in all directions, and various example light rays are illustrated in FIG. 3. Some of the light rays reflect off of the reflective layer 311, the reflective layer 312, or both. Regardless of whether light rays reflect off of the reflective layers 311, 312, the light rays eventually exit the side emitting LED package 300 in multiple different light emission directions. Example light emission directions 301, 302, 303, and 304 are illustrated in FIG. 3. Example light emission direction 304 is illustrated as having an emission angle θ₃ with respect to the rays D and E, which are parallel to the LED chip top surface and substrate top surface, as described in connection with FIG. 2.

Due to the inclined angle(s) of the light converter outer side surface(s), a combination of all light emission angles, such as an average light emission angle or other combination of light emission angles, can be an upward sloping angle, as illustrated in FIG. 3. As a result, displays made with side emitting LED packages described herein can achieve greater brightness, without speckling or spotting effects that could result from removing the cap. The slope of the inclined angle(s) of the light converter outer side surface(s) can be adjusted as needed for particular embodiments, to achieve the desired light emission directions 301, 302, 303, 304.

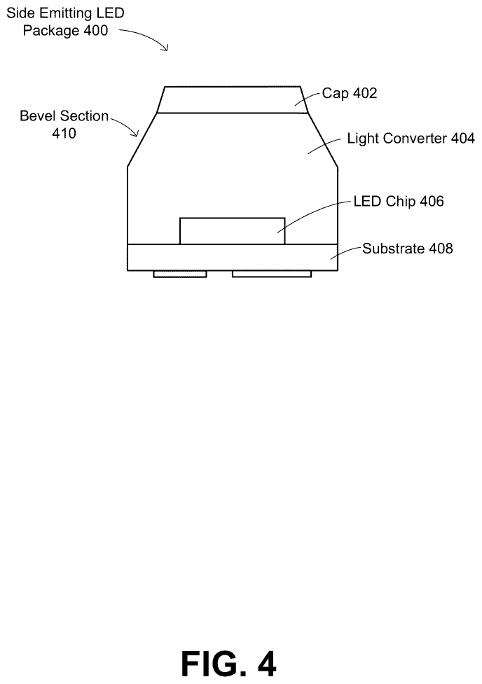

FIG. 4 illustrates another example side emitting LED package, in accordance with one or more embodiments described herein. The example side emitting LED package 400 includes a cap 402, a light converter 404, an LED chip 406, and a substrate 408, which are generally similar to the cap 102, light converter 104, LED chip 106, and substrate 108 introduced in FIG. 1. In FIG. 4, the light converter 404 includes a bevel section 410. The light converter 404 outer side surface(s) are at an inclined angle in the bevel section 410, while the light converter 404 outer side surface(s) are otherwise not at an inclined angle outside the bevel section 410. The light converter 404 can be shaped with a full bevel or partial bevel to adjust the light emission intensity versus emission angle of the side emitting LED package 400. FIG. 4 also demonstrates that there are multiple different approaches to configuring the light converter 404 so that the light converter 404 outer side surface(s) have an inclined angle as described herein.

With regard to FIGS. 1-4, in some embodiments, the substrate components, e.g., substrate 108, can provide a planar surface for mounting of the LED chip 106. Substrate 108 can furthermore provide electrical connectivity to the LED chip 106 from the substrate top surface, and electrical connectivity to a solder pad or other electrical terminals 151 at the bottom side of the side emitting LED package 100. The substrate 108 can be fabricated from a laminate material, e.g., a glass-reinforced epoxy laminate such as FR4, or a bismaleimide triazine (BT) laminate. The substrate 108 can optionally be fabricated using a metal lead frame with molded epoxy resin. For superior light extraction, the surface of the substrate 108 can be coated/laminated with white reflective layer 311 which can optionally have a light reflectivity of 90% or greater.

In some embodiments, the LED chip 106 can be an indium gallium nitride (InGaN) type LED chip. Some example InGaN type LED chips can be adapted to emit light in the near ultraviolet spectrum, e.g., light having wavelengths in the range of 360 nanometers (nm) to 420 nm. Other example InGaN type LED chips can be adapted to emit light in the blue spectrum, e.g., light having wavelengths in the range of 440 nm to 480 nm.

The LED chip 106 can optionally comprise a “flip chip” type base, with both positive (P) and negative (N) terminals at the bottom of the LED chip 106. Alternatively, the LED chip 106 can comprise a vertical chip base, with a P terminal on top of the LED chip 106 and an N terminal at the bottom of the LED chip 106. In another alternative embodiment, the LED chip 106 can comprise a lateral chip base, with both P and N terminals on the top surface of the LED chip 106, and bonded with metal wire.

The LED chip 106 can attach to the substrate 108 by way of, e.g., Eutectic full metal bonding using for example gold-tin (AuSn) or tin-silver-copper (SnAgCu). Alternatively, the LED chip 106 can attach to the substrate 108 using a conductive or non-conductive adhesive.

In some embodiments, the light converter 104 can be made from a mixture of resin and light conversion particles. Example resins suitable for the light converter 104 include epoxy based resins and silicone based resins. The resin can be heat curable or ultraviolet curable. To enhance light extraction from InGaN chip, the material used in the light converter 104 can have a reflective index in the range of 1.3 to 1.6, inclusive.

The light conversion particles in the light converter 104 can include, e.g., phosphor particles. Example phosphor particles include yttrium aluminum garnet (YAG), beta-sialon, potassium fluorosilicate (KSF), silicate and quantum dot particles. Mixtures of different light conversion particles can optionally be used to achieve a specific white light target with good National Television Standards Committee (NTSC) color gamut coverage, e.g., especially for liquid crystal display (LCD) television backlight applications.

In some embodiments, the light converter 104 can be shaped to include a light converter outer side surface which is at an inclined angle in reference to a LED chip 106 side surface, as described with reference to FIG. 2. For example, a light converter 104 outer side surface can be shaped to comprise an inclined angle in the range of 2 to 20 degrees, inclusive, in reference to the LED chip 106 side surface.

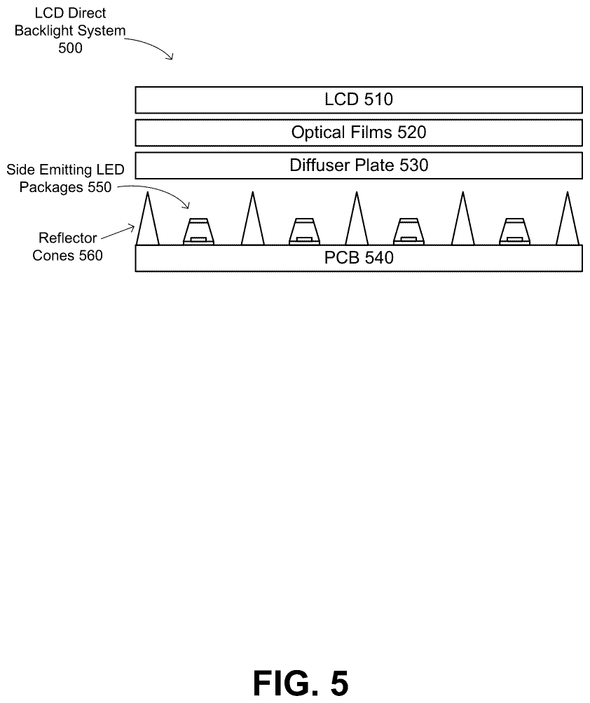

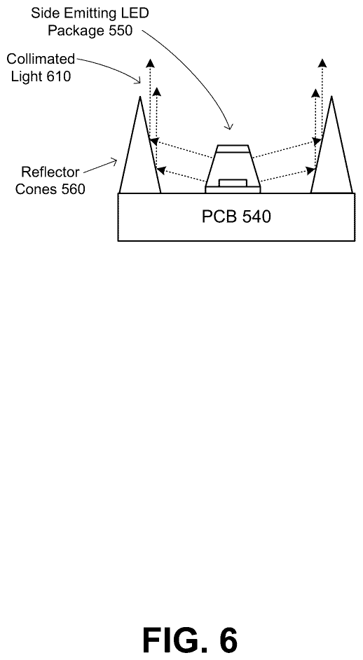

The inclined angle can be selected so that light rays that exit the side emitting LED package 100 are collimated to a defined direction, e.g., upwards from the side emitting LED package, in order to enhance light extraction efficiency. The inclined angle designed for collimation of light can be based in part on angles of any reflective structures surrounding the side emitting LED package 100, e.g., reflector cones such as illustrated in FIGS. 5 and 6.

In some embodiments, the cap 102 can be referred to as a light reflective encapsulant component. The material from which the cap 102 is fabricated can be formulated by a mixture of resin with fine white particles, for example, a mixture of optical clear silicone with titanium dioxide (TiO2), aluminum oxide (Al2O3), and/or barium oxide (BaO). The composition of the cap 102 and/or the reflective layer 312 can be formulated so that the surface of the cap 102 and/or the reflective layer 312 has light reflectivity of 95% or more. The cap 102 and/or the reflective layer 312 can optionally be formed by laminating, molding, or dispensing material on top of the light converter 104. The purpose of the cap 102 includes inhibiting light emission from the top surface of the side emitting LED package 100, in order to prevent bright spots in displays that include the side emitting LED package 100. A majority of the light emitted by side emitting LED package 100 can exit out the sides of the light converter 104.

FIG. 5 illustrates an example LED display including side emitting LED packages, in accordance with one or more embodiments described herein. The example LED display is in the form of LCD direct backlight system 500. It can be appreciated that side emitting LED packages such as disclosed herein can also be incorporated into other LED displays, and the LCD direct backlight system 500 is just one example. The LCD direct backlight system 500 includes various stacked layers, including, from top to bottom, LCD 510, optical films 520, diffuser plate 530, and PCB 540, wherein side emitting LED packages 550 and reflector cones 560 are affixed to the PCB 540. The side emitting LED packages 550 can include, e.g., side emitting LED packages described with reference to FIGS. 1-4. The reflector cones 560 can comprise molded plastic structures optionally coated with a reflective coating.

In some embodiments, the LCD direct backlight system 500 can optionally be used as a display in vehicles such as automobiles, motorcycles, airplanes, busses, trains, or other vehicles. Hundreds or thousands of side emitting LED packages 550 and reflector cones 560 can optionally be included in the LCD direct backlight system 500. The LCD direct backlight system 500 can be configured for localized dimming, wherein subsets of the side emitting LED packages 550 can be activated under portions of the LCD direct backlight system 500 in order to enhance contrast ratios and optionally to boost display brightness under sunlight or other high ambient light conditions.

Due to the high number of side emitting LED packages 550 included in the LCD direct backlight system 500, it can be critical for side emitting LED packages 550 to be efficient in terms of light extraction, so that side emitting LED packages 550 can generate strong brightness using available input electrical power. Furthermore the LCD direct backlight system 500 can provide enhanced LED package light extraction, improved optical efficiency, and reduced degradation of the PCB 540 due to light emitted by the side emitting LED packages 550.

With regard to reduced degradation of the PCB 540, the surface of PCB 540 can be coated with white solder mask. The solder mask can comprise, e.g., epoxy resin. Under prolonged radiation of light from side emitting LED packages 550, the epoxy resin can degrade and turn to brown/yellow color. This can also lead to deterioration of light reflection by the PCB 540. Through the use of side emitting LED packages 550 according to this disclosure, the light that radiates to the surface of PCB 540 is reduced and thus the whiteness/reflectivity of the solder mask on the PCB 540 is prolonged. This can effectively improve the reliability and brightness stability of the whole backlight system 500 under prolonged usage.

In an aspect, FIG. 5 illustrates an LED display comprising a PCB 540, side-emitting LED packages 550 affixed to the PCB 540, reflector cones 560 affixed to the PCB 540, and one or more optical layers 510, 520, 530 positioned over the PCB 540, the side-emitting LED packages 550, and the reflector cones 560. The side-emitting LED packages 550 can comprise features introduced in FIGS. 1-4, such as a light converter 104 with an inclined outer side surface which forms an inclined angle with respect to the PCB 540, a cap 102 over the light converter 104, wherein the cap 102 inhibits light directed perpendicular to the PCB 540, an LED chip 106, and a substrate 108. The reflector cones 560 can be distributed among the side-emitting LED packages 550, e.g., in a repeating honeycomb or other pattern.

FIG. 6 illustrates example light emission from the LED display of FIG. 5, in accordance with one or more embodiments described herein. FIG. 6 illustrates a section of the PCB 540 introduced in FIG. 5, along with some of the reflector cones 560 and one of the side emitting LED packages 550 introduced in FIG. 5. FIG. 6 furthermore illustrate collimated light 610.

As can be understood from FIG. 6, the direction of the collimated light 610 can be substantially perpendicular to the PCB 540. The direction of the collimated light 610 is a function of the aggregate light emission angle of the side emitting LED package 550 and the angles of the reflecting surfaces of the reflector cones 560. In some embodiments, the inclined angle employed by the side emitting LED packages 550 can be selected to produce collimated light 610 in view of the angles of the reflecting surfaces of the reflector cones 560.

FIG. 7 is a three-dimensional view of another example side emitting LED package, in accordance with one or more embodiments described herein. The example side emitting LED package 700 can optionally implement the side emitting LED packages illustrated in FIG. 1-6. The side emitting LED package 700 includes a cap 702, a light converter 704, an LED chip 706, and a substrate 708, which can implement like components illustrated in FIGS. 1-6.

The side emitting LED package 700 is generally rectangular in shape, that is, lateral cross sections of the side emitting LED package 700 are rectangular, and optionally square. In other embodiments, other cross section shapes are also feasible such as round or polygonal such as triangular, hexagonal, or otherwise. In the illustrated embodiment, the light converter 704 comprises four outer side surfaces. The outer side surfaces can have a same inclined angle. In other embodiments, the outer side surfaces can have different inclined angles, or opposing faces of the outer side surfaces can have matching inclined angles.

FIG. 7 illustrates the substrate 708 top surface and the LED chip 706 top surface, both of which can comprise flat planar surfaces. The substrate 708 top surface and the LED chip 706 top surface can be parallel. Furthermore, the LED chip 706 side surfaces can comprise flat planar surfaces, which can be perpendicular to the substrate 708 top surface and the LED chip 706 top surface, as shown. The light converter 704 outer side surfaces can likewise comprise flat planar surfaces, which are at an inclined angle, e.g., angle θ₁ in FIG. 2, with respect to the LED chip 706 side surface, and which are at an inclined angle, e.g., θ₂ in FIG. 2, with respect to the the substrate 708 top surface and the LED chip 706 top surface.

The side emitting LED package 700 includes at least one LED chip 706 positioned over a substrate 708, wherein the at least one LED chip 706 comprises an LED chip 706 side surface that can be defined by a portion of a first plane.

The side emitting LED package 700 furthermore includes a light converter 704 surrounding the LED chip 706, wherein the light converter 704 comprises a light converter 704 outer side surface that can be defined by a portion of a second plane, and wherein the second plane intersects the first plane at an inclined angle. The light converter 704 can be rectangular, and as such can include four total light converter 704 outer side surfaces. A first light converter 704 outer side surface can be defined by the portion of the second plane, as noted above, while the three additional light converter 704 outer side surfaces can be defined by portions of three additional planes, and each of the three additional planes can intersect planes defined by additional LED chip 706 side surfaces at inclined angles.

The inclined angle(s) employed by the light converter 704 can comprise a collimation angle that collimates light rays that exit the side emitting LED package 700. The inclined angle can be, e.g., from 2-20 degrees. In the horizontal plane, the light converter 704 outer side surfaces can be adapted to emit light in substantially three hundred sixty (360) degrees, i.e., in all directions.

The side emitting LED package 700 furthermore includes a cap 702 positioned over the light converter 704. The cap 702 can comprise a reflective bottom surface that can be defined by a portion of a third plane, wherein the third plane can be perpendicular with the first plane, namely, the plane of the LED chip 706 side surface.

The substrate 708 comprises a substrate top surface that can be defined by a portion of another third plane, and the third plane of the substrate top surface can also be perpendicular with the first plane, namely, the plane of the LED chip 706 side surface. The substrate top surface 708 can comprise a laminate material and optionally a reflective layer as illustrated in FIG. 3. At least one first electrical terminal, e.g., of electrical terminals 110 illustrated in FIG. 1, can be disposed in the substrate 708. The at least one first electrical terminal can be adapted to couple with at least one second electrical terminal of electrical terminals 151 on a PCB.

In another aspect, the side emitting LED package 700 is an example of an LED package comprising a substrate 708, at least one LED chip 706 positioned over the substrate 708, a light converter 704 positioned over the substrate 708 and surrounding the LED chip 706, and a cap 702 positioned over the light converter 704, wherein a first perimeter of the light converter 704 adjacent the substrate 708 is larger than a second perimeter of the light converter 704 adjacent the cap 702. The at least one LED chip 706 can comprise an LED chip side surface that can be defined by a portion of a first plane, the light converter 704 can comprise a light converter outer side surface that can be defined by a portion of a second plane, and the second plane can intersect the first plane at an inclined angle, e.g., from 2-20 degrees.

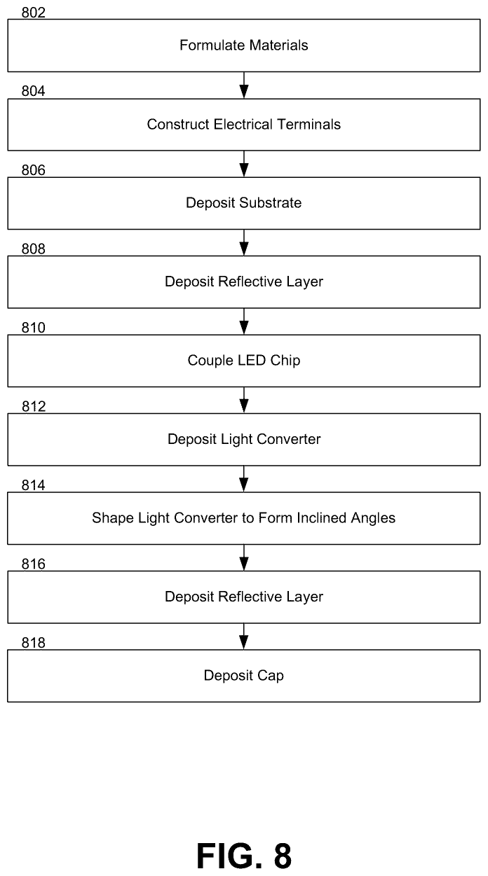

FIG. 8 is a flow diagram of an example method to manufacture a side emitting LED package, in accordance with one or more embodiments described herein. The blocks of the illustrated method represent operations according to a method, as can be appreciated. While the operations are illustrated in sequence, it can furthermore be appreciated that certain operations can optionally be re-ordered, combined, removed or supplemented with other operations in some embodiments.

FIG. 8 comprises a “Formulate Materials” block 802, a “Construct Electrical Terminals” block 804, a “Deposit Substrate” block 806, “Deposit Reflective Layer” block 808, a “Couple LED Chip” block 810, a “Deposit Light Converter” block 812, a “Shape Light Converter to Form Inclined Angles” block 814, a “Deposit Reflective Layer” block 816, and a “Deposit Cap” block 818.

At “Formulate Materials” block 802, the materials described herein for making the substrate 108, reflective layer 311, light converter 104, reflective layer 312, and cap 102 can be mixed in appropriate proportions as desired for particular embodiments. At “Construct Electrical Terminals” block 804, the electrical terminals 110 can be, e.g., positioned in a mold. At “Deposit Substrate” block 806, the formulated material for substrate 108 can be deposited in a layer surrounding the electrical terminals 110. At “Deposit Reflective Layer” block 808, the formulated material for reflective layer 311 can be deposited in a layer over the substrate 108, and optionally polished or otherwise treated for high reflectivity. At “Couple LED Chip” block 810, the LED chip 106 can be coupled over the substrate and adhered to the substrate and electrical terminals 110 using the techniques described herein. At “Deposit Light Converter” block 812, the formulated material for light converter 104 can be deposited in a layer over the substrate 108 and reflective layer 311. At “Shape Light Converter to Form Inclined Angles” block 814, the light converter 104 can be cut or otherwise shaped to form the desired inclined angles of the outer sides of the light converter 104. At “Deposit Reflective Layer” block 816, the formulated material for reflective layer 312 can be deposited in a layer over the light converter 104. At “Deposit Cap” block 818, the formulated material for the cap 102 can be deposited in a layer over the light converter 104 and reflective layer 312. Once fabricated, a side emitting LED package can be soldered or otherwise electrically coupled onto a PCB to build an LED display.

Herein, like reference characters are used throughout the description to reference like structures, functions, and so on. In some cases, some reference characters are omitted for clarity. However, it should be appreciated that, depending on context, identified structures of the various FIGS. may be amenable to being described according to other descriptions of other FIGS. for corresponding structures. Moreover, while various aspects of various FIGS. are presented in isolation from other described aspects of other FIGS. it should be appreciated that, according to desired product specifications, the various aspects presented in isolation can be combined, complemented, and/or substituted in other embodiments, without limitation.

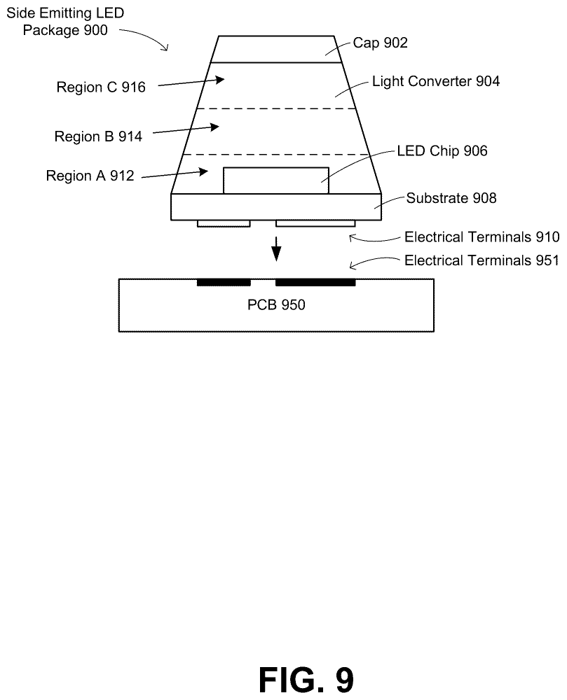

FIG. 9 illustrates an example side emitting LED package 900, in accordance with one or more embodiments described herein. As described above regarding FIGS. 1-8, an example side emitting LED package 900 can comprise a cap 902, a light converter 904, an LED chip 906, a substrate 908, and electrical terminals 910. In addition, electrical terminals 910 are configured to couple with electrical terminals 951 of a PCB 950, as further described herein.

Thus, when the electrical terminals 910 of the side emitting LED package 900 are coupled with the with electrical terminals 951 of the PCB 950, the side emitting LED package 900 can be operated via the PCB 950. The side emitting LED package 900 can be activated, causing the LED chip 906 to emit light. Light emitted by the LED chip 906 passes through the light converter 904 and the light is emitted from the sides of the light converter 904, as further described herein.

In addition, in further non-limiting aspects, an example side emitting LED package 900 can comprise light converter 904 surrounding an LED chip 906 positioned over substrate 908. In an aspect, LED chip 906 can comprise an LED chip side surface that can be defined by a portion of a first plane and light converter 904 can comprise a light converter outer side surface that can be defined by a portion of a second plane, wherein the second plane intersects the first plane at an inclined angle as further described herein. In another non-limiting aspect, exemplary light converter 904 can comprise two or more regions (e.g., region A 912, region B 914, region C 916, etc.), wherein each (e.g., each of region A 912, region B 914, region C 916, etc.) of the two or more regions (e.g., region A 912, region B 914, region C 916, etc.) can have a differing material composition than one or more other region (e.g., region A 912, region B 914, region C 916, etc.) of the two or more regions (e.g., region A 912, region B 914, region C 916, etc.), for example, as further described herein. In still further non-limiting aspects, exemplary differing material compositions can differ in one or more of refractive index, light conversion efficiency sensitivity to temperature, reflectivity or light diffusion level, for example, as further described herein.

For example, in further non-limiting aspects, an example side emitting LED package 900 can comprise LED chip 906 comprising an indium gallium nitride (InGaN) LED chip 906 or an aluminum indium gallium phosphide (AlInGaP) LED chip 906. In the exemplary LED chip 906 comprising an indium gallium nitride (InGaN) LED chip 906 it can be understood that refractive index of such a chip can ranges from about 2.4 to 2.9, which value depends on the composition (In/Ga ratio) and the wavelength of the emitted light. In the exemplary LED chip 906 comprising an aluminum indium gallium phosphide (AlInGaP) LED chip 906 it can be understood that refractive index of such a chip can ranges from about 3.0 to 3.6, which value likewise depends on the composition and the wavelength of the emitted light. It can be further understood that when light travels from a material with a high refractive index (e.g., LED chip 906) to a material with a lower refractive index (e.g., air having refractive index approximately 1.0), total internal reflection can occur at the interface, causing light to be trapped within the LED chip 906. Thus, in non-limiting aspects, exemplary light converter 904 can employ a higher refractive index material, closer to that of LED chip 906, which can increase the critical angle for total internal reflection, thereby allowing more light to escape from the LED chip 906 to the surrounding resin of light converter 904.

Accordingly, in non-limiting embodiments described herein, exemplary light converter 904 can employ two or more regions (e.g., region A 912, region B 914, region C 916, etc.), wherein each (e.g., each of region A 912, region B 914, region C 916, etc.) of the two or more regions (e.g., region A 912, region B 914, region C 916, etc.) can have a differing material composition than one or more other region (e.g., region A 912, region B 914, region C 916, etc.) of the two or more regions (e.g., region A 912, region B 914, region C 916, etc.), wherein the differing material compositions can differ in refractive index, for example, as further described herein. Thus, in non-limiting aspects, region A 912, region B 914, region C 916 can comprise differing material compositions that differ in refractive index according to distance away from the LED chip 906 and towards the cap 902, for example, as further described herein.

For instance, exemplary light converter 904 can employ a resin in region A 912 having refractive index of about 1.4 to about 1.7, the highest refractive index being closest to the LED chip 906. In another non-limiting aspect, exemplary light converter 904 can employ a resin in region B 914 having refractive index of about 1.3 to about 1.6. In addition, exemplary light converter 904 can employ a resin in region C 916 having refractive index of about 1.2 to about 1.5, the lowest refractive index being closest to the cap 902 and furthest away from the LED chip 906. Accordingly, by employing a gradual refractive index change from the LED chip 906 to the cap 902 or environment interface, exemplary LED chip 906 can create a smoother transition for light moving from the LED chip 906 to the environment, which can reduce scattering and reflection losses, and which can increase efficiency of light extraction from the LED package 900.

In addition, it can be understood that, during operation, exemplary LED chip 906 can typically convert about 40 percent (%) of input electrical energy to visible light, with the balance of about 60% of input electrical energy being lost as generated heat. Thus, exemplary LED chip 906 surface can have elevated temperature as high as 125 degrees Celsius (C), depending on the LED package 900 driving conditions, surrounding environmental temperatures, and heat management structures and processes during operation of exemplary LED package. As a result, certain applications of exemplary light converter 904 experience what is known as thermal quenching, whereby a light converter element 904 material, for example, potassium fluorosilicate (KSF), silicate, quantum dot particles, and so on, can lose conversion efficiency at elevated temperatures due to increased non-radiative recombination processes, which can result in decreased light output and a shift in color temperature. In addition, excessive temperatures can also lead to poor reliability. For instance, high temperatures can cause degradation of the phosphor materials, quantum dot particles, and so on, leading to a reduction in brightness and changes in color over time. This degradation and loss of reliability can be particularly problematic in high-power LEDs where significant heat is generated. However, other phosphors, such as nitride-based phosphors, beta-sialon based phosphors, and so on can exhibit better thermal stability and can be less prone to thermal quenching.

Accordingly, in non-limiting embodiments described herein, exemplary light converter 904 can employ two or more regions (e.g., region A 912, region B 914, region C 916, etc.), wherein each (e.g., each of region A 912, region B 914, region C 916, etc.) of the two or more regions (e.g., region A 912, region B 914, region C 916, etc.) can have a differing material composition than one or more other region (e.g., region A 912, region B 914, region C 916, etc.) of the two or more regions (e.g., region A 912, region B 914, region C 916, etc.), wherein the differing material compositions can differ in light conversion efficiency sensitivity to temperature, for example, as further described herein. Thus, in non-limiting aspects, region A 912, region B 914, region C 916 can comprise differing material compositions that differ in light conversion efficiency sensitivity to temperature according to distance away from the LED chip 906 and towards the cap 902, for example, as further described herein. Thus, various embodiments described herein can include an exemplary multi-region light converter 904 element, which can vary light conversion efficiency sensitivity to temperature according to distance away from the LED chip 906, where the materials which are more sensitive to heat can be positioned further from the LED chip 906, which can enhance the optical efficiency of the LED package 900 during application and minimize shift in color over time.

In addition, according to various embodiments, diffusing agents can be added to resin(s) of exemplary multi-region light converter 904 element to help spread light emitted from exemplary LED chip 906 more evenly during light converter 904 layer formation. Accordingly, in non-limiting embodiments described herein, exemplary light converter 904 can employ two or more regions (e.g., region A 912, region B 914, region C 916, etc.), wherein each (e.g., each of region A 912, region B 914, region C 916, etc.) of the two or more regions (e.g., region A 912, region B 914, region C 916, etc.) can have a differing material composition than one or more other region (e.g., region A 912, region B 914, region C 916, etc.) of the two or more regions (e.g., region A 912, region B 914, region C 916, etc.), wherein the differing material compositions can differ in light diffusion level, for example, as further described herein. Thus, in non-limiting aspects, region A 912, region B 914, region C 916 can comprise differing material compositions that differ in light diffusion level according to distance away from the LED chip 906 and towards the cap 902, for example, as further described herein.

In non-limiting aspects, for example, highest light diffusion level and the lowest light diffusion level can vary as a result of differing concentrations of light diffusing agents in the two or more regions (e.g., region A 912, region B 914, region C 916, etc.) of exemplary light converter 904, wherein the light scattering agents can comprise one or more of silica (SiO₂) particles, titanium dioxide (TiO₂) particles, barium sulfate (BaSO₄) particles, and/or alumina (Al₂O₃) particles. Thus, as the amount or concentration of light scattering agents is increased the in the resin(s), the more light loss can occur within the LED package 900 due to total internal reflection. According to further embodiments, the balance between light uniformity and optical efficiency can be varied according to the design requirements for the LED package 900. As a non-limiting example, by varying the light diffusion level as a result of differing concentrations of light diffusing agents in the two or more regions (e.g., region A 912, region B 914, region C 916, etc.) of exemplary light converter 904, a balance between light uniformity and optical efficiency can be achieved. In a further non-limiting aspect, exemplary embodiments can have a material composition that has highest light diffusion level nearest the LED chip 906 (e.g., region A 912) and material composition that has lowest light diffusion level nearest the cap 902, (e.g., furthest from LED chip 906 (e.g., region C 916)), or approximately equal to zero (e.g., optically clear) in certain applications.

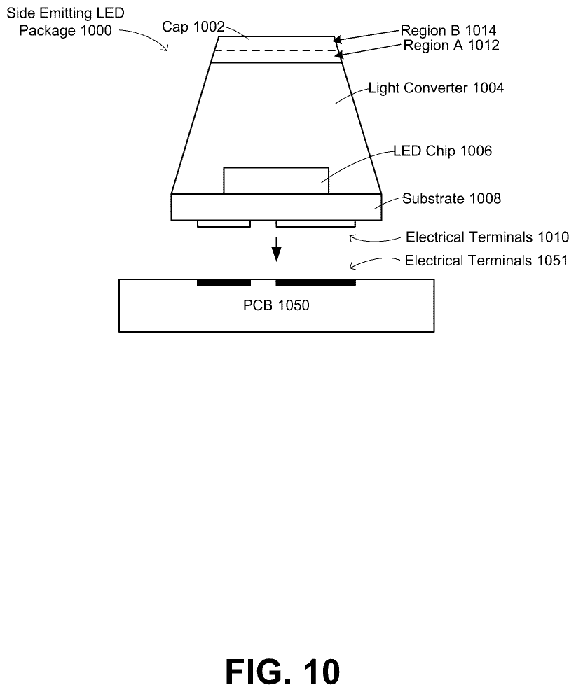

FIG. 10 illustrates another example side emitting LED package 1000, in accordance with one or more further embodiments described herein. As described above regarding FIGS. 1-8, an example side emitting LED package 1000 comprises a cap 1002, a light converter 1004, an LED chip 1006, a substrate 1008, and electrical terminals 1010. In addition, the electrical terminals 1010 are configured to couple with electrical terminals 1051 of a PCB 1050, as further described herein.

Thus, when the electrical terminals 1010 of the side emitting LED package 1000 are coupled with the with electrical terminals 1051 of the PCB 1050, the side emitting LED package 1000 can be operated via the PCB 1050. The side emitting LED package 1000 can be activated, causing the LED chip 1006 to emit light. Light emitted by the LED chip 1006 passes through the light converter 1004 and the light is emitted from the sides of the light converter 1004, as further described herein.

In certain applications, such as liquid crystal displays (LCDs) employing direct backlight LEDs, it is desired to make the displays as thin as possible. Referring again to FIG. 5, it can be seen that as display thickness is reduced, the diffuser plate 530 to LED package 550 is reduced. If cap 102 completely blocks light rays emanating from the top of the LED package 550, a dim zone can be created between cap 102 of LED package 550 and diffuser plate 530, which can result in poor LCD backlight brightness uniformity.

Referring again to FIG. 10, in various described embodiments, an exemplary cap 1002 can comprise two or more regions (e.g., region A 1012, region B 1014, etc.), wherein each (e.g., each of region A 1012, region B 1014, etc.) of the two or more regions (e.g., region A 1012, region B 1014, etc.) can have a different material composition than one or more other region (e.g., region A 1012, region B 1014, etc.) of the two or more regions (e.g., region A 1012, region B 1014, etc.), for example, as further described herein. According to further non-limiting aspects, material composition of the two or more regions (e.g., region A 1012, region B 1014, etc.) can be different in one or more of reflectivity and/or light diffusion level.

As a result, in non-limiting aspects, an exemplary cap 1002 can be formed with varying reflectance and diffusion level to distribute the ratio of light emitted upwards from cap 1002 and ratio of light emitted sideward from exemplary light converter 1004. In further non-limiting aspects, varying reflectance and diffusion level can enhance light distribution uniformity, in various embodiments. As further described herein, diffusion level and reflectance level of exemplary cap 1002 can be adjusted by varying the loading of light diffusion and reflectance components including, but not limited to silica (SiO₂) particles, titanium dioxide (TiO₂) particles, barium sulfate (BaSO₄) particles, and/or alumina (Al₂O₃) particles.

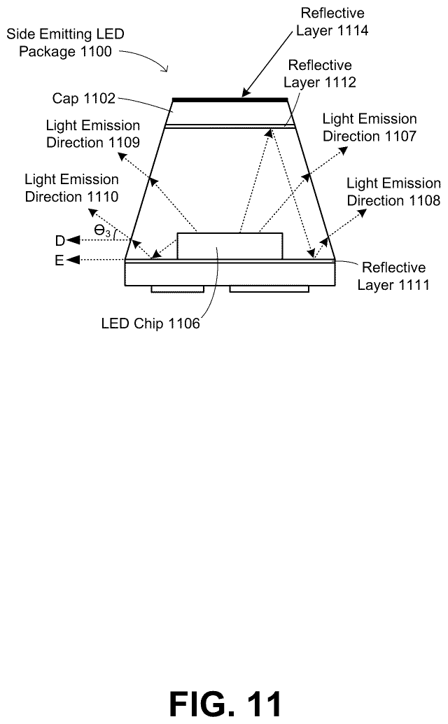

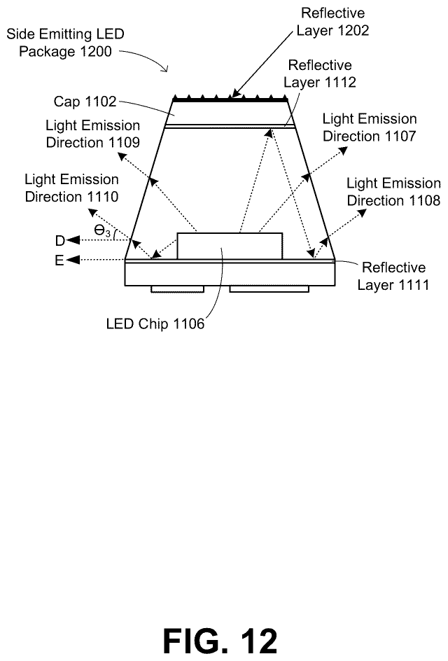

FIG. 11 illustrates example light emission from a side emitting LED package 1100, in accordance with one or more embodiments described herein. FIG. 12 further illustrates example light emission from a side emitting LED package 1200, in accordance with one or more other embodiments described herein. FIGS. 11-12 include an example side emitting LED package 1100, 1200 having components generally similar to those introduced in FIGS. 1, 9, for example. In FIGS. 11-12, cap 1102 can include an example reflective layer 1112, and the substrate also includes a reflective layer 1111.

In further non-limiting aspects, exemplary side emitting LED packages 1100, 1200 can further include a cap 1102 that can comprise a reflective top surface. For instance, exemplary side emitting LED packages 1100, 1200 can further include a cap 1102 that can comprise a reflective layer 1114, 1202 on a top surface of the cap 1102, opposite of the LED chip 1106, configured to reflect light incident on the cap 1102 that is reflected back in a direction of the LED package 1100, 1200 (e.g., from an exemplary diffuser plate 530 or other structure comprising LED package 1100, 1200). In still further non-limiting aspects, exemplary reflective layer 1114, 1202 on a top surface of cap 1102 can comprise a coating 1114 or a micro-reflector array 1202 on the top surface of the cap 1102 or another layer adjacent to the top surface of the cap 1102. In another non-limiting aspect, an exemplary micro-reflector array 1202 can comprise a self-assembled micro-reflector array 1202, an etched micro-reflector array 1202, and so on.

Accordingly, as further described above regarding FIG. 3, light rays are emitted by the LED 1106 chip in all directions, and various example light rays are illustrated in FIGS. 11-12. Some of the light rays reflect off of the reflective layer 1111, the reflective layer 1112, or both. Regardless of whether light rays reflect off of the reflective layers 1111, 1112, the light rays eventually exit the side emitting LED package 1100 in multiple different light emission directions. Example light emission directions 1107, 1108, 1109, and 1110 are illustrated in FIG. 11. Example light emission direction 1110 is illustrated as having an emission angle θ₃ with respect to the rays D and E, which are parallel to the LED chip top surface and substrate top surface, as described in connection with FIG. 2.

Due to the inclined angle(s) of the light converter outer side surface(s), a combination of all light emission angles, such as an average light emission angle or other combination of light emission angles, can be an upward sloping angle, as illustrated in FIG. 11. As a result, displays made with side emitting LED packages described herein can achieve greater brightness, without speckling or spotting effects that could result from removing the cap. The slope of the inclined angle(s) of the light converter outer side surface(s) can be adjusted as needed for particular embodiments, to achieve the desired light emission directions 1107, 1108, 1109, 1110.

However, as further described above regarding FIGS. 5 and 10, for example, as LCD thickness is reduced, distance from diffuser plate 530 to LED package 550 is reduced. If cap 102 completely blocks light rays emanating from the top of the LED package 550, a dim zone can be created between cap 102 of LED package 550 and diffuser plate 530, which can result in poor LCD backlight brightness uniformity. However, various embodiments employing exemplary reflective layer 1114, 1202 can facilitate reflecting light that is incident on the cap 1102, such as for example, light that is reflected back in a direction of the LED package 1100, 1200 from an exemplary diffuser plate 530, for example, as further described herein.

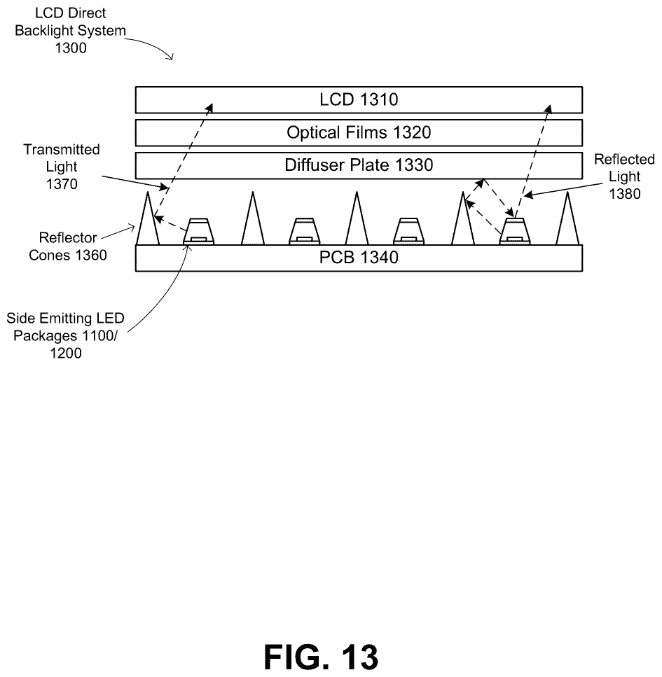

For instance, FIG. 13 illustrates another example LED display including side emitting LED packages, in accordance with one or more embodiments described herein. As further described herein regarding FIG. 5, for example, an exemplary LED display in the form of LCD direct backlight system 1300 can employ side emitting LED packages 1100, 1200 (as well as other described embodiments), which can also be incorporated into other LED displays. The LCD direct backlight system 1300 includes various stacked layers, including, from top to bottom, LCD 1310, optical films 1320, diffuser plate 1330, and PCB 1340, wherein side emitting LED packages 1100, 1200 and reflector cones 1360 are affixed to the PCB 1340, as further described herein. For instance, side emitting LED packages 1100, 1200 can include, e.g., side emitting LED packages described with reference to FIGS. 1-4, 9-12, etc. The reflector cones 1360 can comprise molded plastic structures optionally coated with a reflective coating. Various aspects of LCD direct backlight system 1300 can be further understood by reference to the analogous structures and processes described herein regarding FIG. 5, for example.

In further non-limiting aspects, whereas light emanating from side emitting LED packages 1100, 1200 is intended to be transmitted sideways against reflector cones 1360 and across the layers of the diffuser plate 1330 and the optical films 1320 to the LCD 1310 as transmitted light 1370, it is understood that some amount of light would be reflected at the interface of diffuser plate 1330 as reflected light 1380. Thus, various embodiments employing exemplary reflective layer 1114, 1202 (or partially reflective cap as described regarding cap 1002 in FIG. 10) can facilitate reflecting light that is incident on the cap 1102, such as for example, light that is reflected back in a direction of the LED package 1100, 1200 from an exemplary diffuser plate 1330, for example. As a result, various embodiments employing exemplary reflective layer 1114, 1202 (or partially reflective cap as described regarding cap 1002 in FIG. 10) on the cap 1102 can facilitate reflecting the reflected light 1380 back toward LCD 1310, thus improving optical efficiency of the LCD direct backlight system 1300.

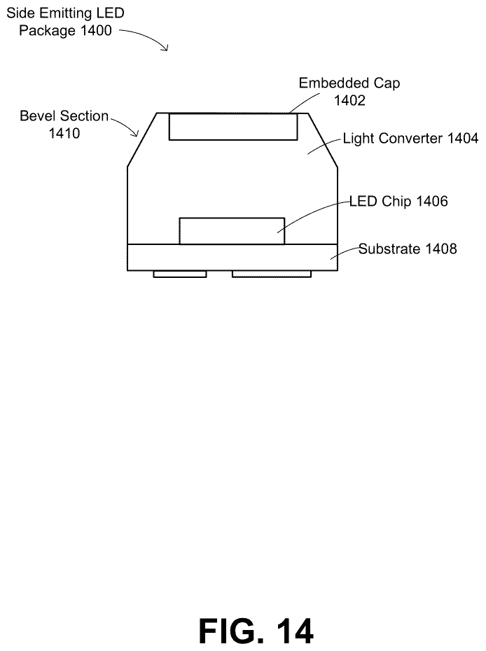

FIG. 14 illustrates another example side emitting LED package 1400, in accordance with one or more further embodiments described herein. For instance, example side emitting LED package 1400 includes a cap 1402 that can be at least partially embedded within a light converter 1404, an LED chip 1406, and a substrate 1408, which are generally similar to the cap 102, light converter 104, LED chip 106, and substrate 108 as further described regarding FIG. 1, 4, 9, and so on. In FIG. 14, the light converter 1404 includes a bevel section 1410, as further described herein. The light converter 1404 outer side surface(s) are at an inclined angle in the bevel section 1410, while the light converter 1404 outer side surface(s) are otherwise not at an inclined angle outside the bevel section 1410. The light converter 1404 can be shaped with a full bevel or partial bevel to adjust the light emission intensity versus emission angle of the side emitting LED package 1400, as further described herein. FIG. 14 also demonstrates that there are multiple different approaches to configuring the light converter 1404 so that the light converter 1404 outer side surface(s) have an inclined angle as described herein.

Further details of FIGS. 9-14 and 15-17 including, but not limited to, arrangement, structure, function, application, and/or composition can be understood by review of description herein of FIGS. 1-8, for example.

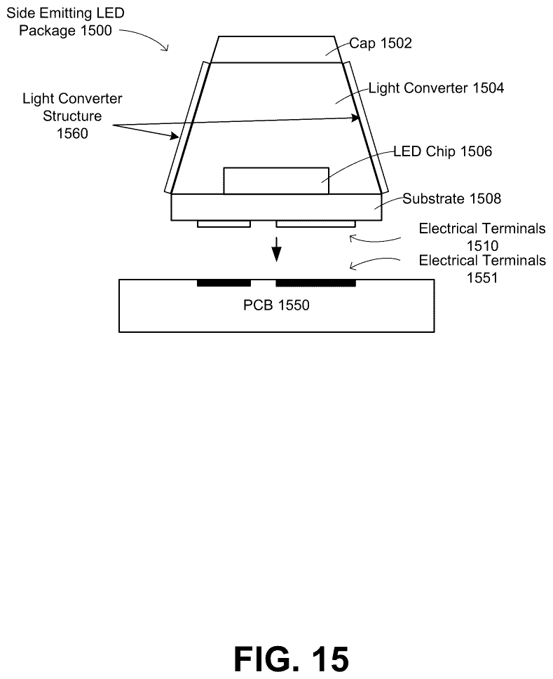

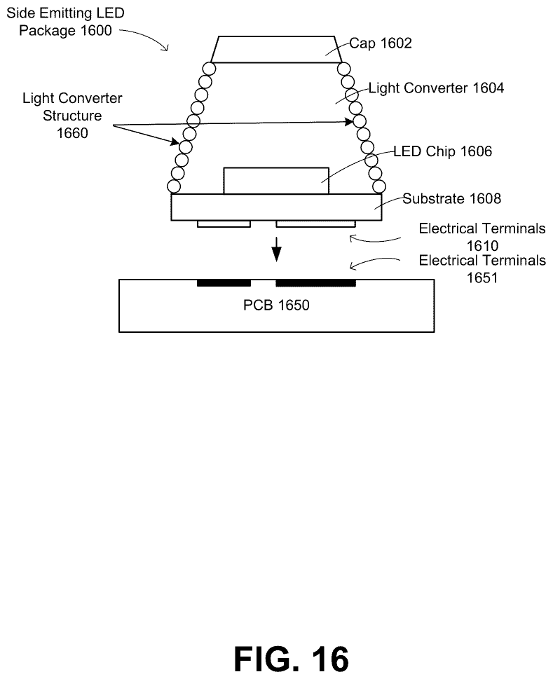

In addition, FIG. 15 illustrates another example side emitting LED package 1500, in accordance with one or more embodiments described herein, for example, regarding FIGS. 1-8, 9-14, and so on. Similarly, FIG. 16 illustrates still another example side emitting LED package 1600, in accordance with one or more embodiments described herein.

The example side emitting LED package 1500, 1600 comprises a cap 1502, 1602, a light converter 1504, 1604, an LED chip 1506, 1606, a substrate 1508, 1608, and electrical terminals 1510, 1610. The electrical terminals 1510, 1610 are configured to couple with electrical terminals 1551, 1651 of a PCB 1550, 1650, as further described herein.

Accordingly, when the electrical terminals 1510, 1610 of the side emitting LED package 1500, 1600 are coupled with the with electrical terminals 1551, 1651 of the PCB 1550, 1650, the side emitting LED package 1500, 1600 can be operated via the PCB 1550, 1650. The side emitting LED package 1500, 1600 can be activated, causing the LED chip 1506, 1606 to emit light. Light emitted by the LED chip 1506, 1606 passes through the light converter 1504, 1604 and the light is emitted from the sides of the light converter 1504, 1604, as further described herein.

Accordingly, various embodiments described herein can comprise a structure (e.g., light converter structure 1560, 1660 of the light converter 1504, 1604) located adjacent to light converter 1504, 1604 configured to prevent contaminant absorption into a material of the light converter 1504, 1604 or promote light escape from the light converter 1504, 1604 to a surrounding environment.

For instance, LED package 1500 (as well as other described embodiments) according to various embodiments can have large light emitting surface (e.g., 4 sides) compared to an LED package that has light emitting surface from only from the package top side. High air permeability of a silicone resin that can be employed as base material of light converter 1504 layer can permit moisture and/or ionic contamination to penetrate into the LED package 1500 via light converter 1504 surface. In addition, at elevated temperatures, high moisture, and/or high ionic concentration, metal migration within LED package 1500 can cause pre-mature LED package 1500 failure due to electrical leakage or short circuits.

Accordingly, LED package 1500 (as well as other described embodiments) can employ light converter structure 1560 of the light converter 1504 as a barrier coating at the outer surface of light converter 1504 that can protect against metal migration as described herein, which would otherwise be accelerated by air/moisture/ionic contamination. In another non-limiting aspect, an exemplary light converter structure 1560 of the light converter 1504 as a barrier coating can be deposited around the light converter by way of dispensing, jetting, coating, lamination, molding process using resin material with low moisture/air permeability, and so on. In yet another non-limiting aspect, an exemplary barrier coating around the light converter 1504 cane be formed by way of atomic layer deposition (ALD) by depositing layers of material which has low moisture/air permeability, including, but not limited to silicon dioxide (SiO₂), silicon nitride (SiN), aluminum oxide (Al₂O₃), titanium oxide (TiO₂), and the like.

Accordingly, further embodiments described herein can comprise a structure (e.g., light converter structure 1660 of the light converter 1604) located adjacent to light converter 1604 configured to promote light escape from the light converter 1604 to a surrounding environment. For example, inclined outer side surfaces of light converter 1604 can be treated to form a nanostructure or coated with a nano-structured material to enhance light ray escape from light converter 1604 to the surrounding environment. For instance, when light travels from a material with a high refractive index (e.g., light converter 1604 having resin with refractive index of around 1.3) to a material with a lower refractive index (e.g., air with refractive index approximately 1.0), total internal reflection can occur at the interface, causing light to be trapped within light converter 1604.

Thus, in non-limiting aspects, an exemplary light converter 1604 surface can be polished and/or coated with optical polymer to smoothen the surface to ease the light transmittance out to the surrounding environment. In a further non-limiting aspect, exemplary light converter 1604 can be shaped, for example, by roughing (e.g., sand blasting), coating of nano-structured material, and so on to increase the surface area of light converter 1604 outer surface to facilitate increasing the amount of light transmitted to the surrounding environment.

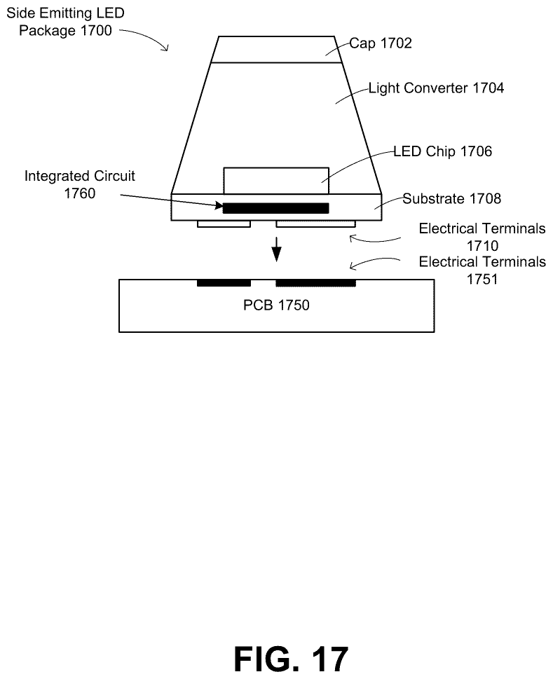

FIG. 17 illustrates an example side emitting LED package 1700, in accordance with one or more embodiments described herein. As described above regarding FIGS. 1-8, an example side emitting LED package 1700 can comprise a cap 1702, a light converter 1704, an LED chip 1706, a substrate 1708, and electrical terminals 1710. In addition, electrical terminals 1710 are configured to couple with electrical terminals 1751 of a PCB 1750, as further described herein.

Thus, when the electrical terminals 1710 of the side emitting LED package 1700 are coupled with the with electrical terminals 1751 of the PCB 1750, the side emitting LED package 1700 can be operated via the PCB 1750. The side emitting LED package 1700 can be activated, causing the LED chip 1706 to emit light. Light emitted by the LED chip 1706 passes through the light converter 1704 and the light is emitted from the sides of the light converter 1704, as further described herein.

In addition, in further non-limiting aspects, an example side emitting LED package 1700 can comprise an exemplary integrated circuit component 1760 associated with substrate 1708. In a non-limiting aspect, substrate 1708 can further comprise multiple layers with embedded integrated circuit 1760 for driving the LED chip 1706. In still further non-limiting aspects, substrate 1708 further can comprise an embedded Zener chip to enhance electrostatic discharge (ESD) protection. In yet another non-limiting aspect, a temperature sensor can be integrated into the substrate 1708 to monitor the operating temperature of the LED chip 1706.

For instance, substrate 1708 in the described LED package 1700 can comprise multiple layers, each with specific functionalities. Exemplary layers can be designed to embed integrated circuit 1760 that can drive LED chip 1706 and/or integrated circuit 1760 can include components such as transistors, resistors, and capacitors, which are essential for regulating the power supply and controlling the operation of the LED chip 1706, ensuring optimal performance and energy efficiency. In various embodiments, embedding integrated circuit 1760 substrate 1708 can reduce the overall footprint of the LED package 1700 and thermal management can be improved.

In other embodiments, substrate 1708 can include an embedded Zener chip designed to enhance ESD protection, which is crucial in preventing damage to the LED chip 1706 and other sensitive components from sudden electrical discharges. An exemplary Zener chip can be strategically embedded within the substrate 1708 adjacent to LED chip 1706 to provide effective ESD protection, which can function by clamping voltage spikes and dissipating excess energy, thereby safeguarding the LED chip 1706 and associated circuitry from potential damage.

In still other non-limiting implementations optimal operating conditions of the LED chip 1706 can be maintained by including a temperature sensor integrated into the substrate 1708. An exemplary temperature sensor can facilitate continuously monitoring operating temperature of the LED chip 1706, which can provide real-time data for thermal management. In non-limiting aspects, an exemplary integrated temperature sensor can be placed in close proximity to the LED chip 1706 to accurately monitor its operating temperature, which sensor can be connected to the integrated circuit 1760, and which can adjust the power supply to the LED chip 1706 based on temperature. By monitoring the temperature in real-time, the exemplary side emitting LED package 1700 can prevent overheating and can maintain the LED chip 1706 within safe operating limits, which can enhance the longevity and performance of exemplary side emitting LED package 1700.

Accordingly, non-limiting embodiments described herein can comprise an LED package (e.g., LED package 900, 1000, 1100, 1200, 1400, 1500, 1600, 1700). In non-limiting aspects, exemplary LED package (e.g., LED package 900, 1000, 1100, 1200, 1400, 1500, 1600, 1700) can comprise a light converter (e.g., light converter 904, 1004, 1404, 1504, 1604, 1704) surrounding an LED chip (e.g., LED chip 906, 1006, 1106, 1406, 1506, 1606, 1706) positioned over a substrate (e.g., substrate 908, 1008, 1408, 1508,1608, 1708), wherein the LED chip (e.g., LED chip 906, 1006, 1106, 1406, 1506, 1606, 1706) can comprise an LED chip (e.g., LED chip 906, 1006, 1106, 1406, 1506, 1606, 1706) side surface that can be defined by a portion of a first plane, wherein the light converter (e.g., light converter 904, 1004, 1404, 1504, 1604, 1704) can comprise a light converter (e.g., light converter 904, 1004, 1404, 1504, 1604, 1704) outer side surface that can be defined by a portion of a second plane, and wherein the second plane intersects the first plane at an inclined angle, wherein the light converter (e.g., light converter 904, 1004, 1404, 1504, 1604, 1704) can comprise two or more regions, and wherein each of the two or more regions has a differing material composition from at least one other of the two or more regions.

In further non-limiting aspects, exemplary light converter (e.g., light converter 904, 1004, 1404, 1504, 1604, 1704) can comprise a mixture of resin and light conversion particles. For instance, exemplary light conversion particles can comprise one or more of nitride-based phosphor particles, beta-sialon-based phosphor particles, silicate particles, potassium fluorosilicate (KSF) particles, or quantum dot particles, as further described herein.

In still other non-limiting aspects, LED chip (e.g., LED chip 906, 1006, 1106, 1406, 1506, 1606, 1706) can comprise an indium gallium nitride (InGaN) type LED chip (e.g., LED chip 906, 1006, 1106, 1406, 1506, 1606, 1706) or an aluminum indium gallium phosphide (AlInGaP) type LED chip (e.g., LED chip 906, 1006, 1106, 1406, 1506, 1606, 1706).

Further non-limiting implementations can provide exemplary LED packages (e.g., LED package 900, 1000, 1100, 1200, 1400, 1500, 1600, 1700), wherein the differing material composition differs in one or more of refractive index, light conversion efficiency sensitivity to temperature, or light diffusion level, as further described herein. In other non-limiting implementations exemplary LED packages (e.g., LED package 900, 1000, 1100, 1200, 1400, 1500, 1600, 1700) can comprise at least three regions, which regions can vary in the differing material composition according to the distance away from the LED chip (e.g., LED chip 906, 1006, 1106, 1406, 1506, 1606, 1706) and towards the cap, for example, as further described herein. For instance, an exemplary LED package (e.g., LED package 900, 1000, 1100, 1200, 1400, 1500, 1600, 1700) can comprise a first region of having a first material composition nearest the LED chip (e.g., LED chip 906, 1006, 1106, 1406, 1506, 1606, 1706), a second region a second material composition, and a third region having a third material composition nearest the cap. In non-limiting aspects, a first region can have a highest refractive index and the third region can have a lowest refractive index. In other non-limiting aspects, a first region can have a lowest light conversion efficiency sensitivity to temperature and the third region can have a highest light conversion efficiency sensitivity to temperature.

In still other non-limiting aspects, a first region can have a highest light diffusion level and the third region can have a lowest light diffusion level. As a non-limiting example, embodiments of The LED package (e.g., LED package 900, 1000, 1100, 1200, 1400, 1500, 1600, 1700) can comprise highest light diffusion level and the lowest light diffusion level, which vary as a result of differing concentrations of light diffusing agents in the regions of the light converter (e.g., light converter 904, 1004, 1404, 1504, 1604, 1704), wherein the light scattering agents comprise one or more of silica (SiO₂) particles, titanium dioxide (TiO₂) particles, barium sulfate (BaSO₄) particles, or alumina (Al₂O₃) particles, as further described herein.

In further non-limiting aspects, exemplary LED package (e.g., LED package 900, 1000, 1100, 1200, 1400, 1500, 1600, 1700) can comprise a cap (e.g., cap 902, 1002, 1102, 1402, 1502, 1602, 1702) positioned adjacent to and in contact with the light converter (e.g., light converter 904, 1004, 1404, 1504, 1604, 1704) and characterized by continuous contact between the cap (e.g., cap 902, 1002, 1102, 1402, 1502, 1602, 1702) and a top surface of the light converter (e.g., light converter 904, 1004, 1404, 1504, 1604, 1704) across an entirety of a bottom surface of the cap, wherein area of the bottom surface of the cap (e.g., cap 902, 1002, 1102, 1402, 1502, 1602, 1702) is less than area of the light converter (e.g., light converter 904, 1004, 1404, 1504, 1604, 1704) adjacent to the substrate (e.g., substrate 908, 1008, 1408, 1508,1608, 1708).

In yet another non-limiting aspect, exemplary LED package (e.g., LED package 900, 1000, 1100, 1200, 1400, 1500, 1600, 1700) comprising cap (e.g., cap 902, 1002, 1102, 1402, 1502, 1602, 1702) can comprise a reflective top surface, as further described herein. In addition, exemplary LED package (e.g., LED package 900, 1000, 1100, 1200, 1400, 1500, 1600, 1700) can further comprise a reflective layer on a top surface of the cap, opposite of the LED chip (e.g., LED chip 906, 1006, 1106, 1406, 1506, 1606, 1706), configured to reflect light incident on the cap (e.g., cap 902, 1002, 1102, 1402, 1502, 1602, 1702) that is reflected back in a direction of the LED package. For instance, exemplary reflective layer on a top surface of the cap (e.g., cap 902, 1002, 1102, 1402, 1502, 1602, 1702) can comprise one or more of a coating or a micro-reflector array on the top surface of the cap (e.g., cap 902, 1002, 1102, 1402, 1502, 1602, 1702) or another layer adjacent to the top surface of the cap (e.g., cap 902, 1002, 1102, 1402, 1502, 1602, 1702) and comprising one or more of a self-assembled micro-reflector array or an etched micro-reflector array, in further non-limiting aspects.

In other non-limiting embodiments, exemplary LED package (e.g., LED package 900, 1000, 1100, 1200, 1400, 1500, 1600, 1700) can comprise a cap (e.g., cap 902, 1002, 1102, 1402, 1502, 1602, 1702) that is at least partially embedded into the light converter (e.g., light converter 904, 1004, 1404, 1504, 1604, 1704). In still other non-limiting embodiments, exemplary LED package (e.g., LED package 900, 1000, 1100, 1200, 1400, 1500, 1600, 1700) can comprise a cap (e.g., cap 902, 1002, 1102, 1402, 1502, 1602, 1702) that can comprise two or more regions, and wherein each of the two or more regions can a different material composition from another of the two or more regions, such as, for example, differing material compositions that differs in one or more of reflectivity or light diffusion level.

In still further non-limiting embodiments, an exemplary LED package (e.g., LED package 900, 1000, 1100, 1200, 1400, 1500, 1600, 1700) can comprise a light converter (e.g., light converter 904, 1004, 1404, 1504, 1604, 1704) surrounding an LED chip (e.g., LED chip 906, 1006, 1106, 1406, 1506, 1606, 1706) positioned over a substrate (e.g., substrate 908, 1008, 1408, 1508, 1608, 1708), wherein the LED chip (e.g., LED chip 906, 1006, 1106, 1406, 1506, 1606, 1706) can comprise an LED chip (e.g., LED chip 906, 1006, 1106, 1406, 1506, 1606, 1706) side surface that can be defined by a portion of a first plane, wherein the light converter (e.g., light converter 904, 1004, 1404, 1504, 1604, 1704) can comprise a light converter (e.g., light converter 904, 1004, 1404, 1504, 1604, 1704) outer side surface that can be defined by a portion of a second plane, and wherein the second plane intersects the first plane at an inclined angle

In other non-limiting implementations, an exemplary LED package (e.g., LED package 900, 1000, 1100, 1200, 1400, 1500, 1600, 1700) can comprise a cap (e.g., cap 902, 1002, 1102, 1402, 1502, 1602, 1702) positioned adjacent to and in contact with the light converter (e.g., light converter 904, 1004, 1404, 1504, 1604, 1704) and characterized by continuous contact between the cap (e.g., cap 902, 1002, 1102, 1402, 1502, 1602, 1702) and a top surface of the light converter (e.g., light converter 904, 1004, 1404, 1504, 1604, 1704) across an entirety of a bottom surface of the cap, wherein area of the bottom surface of the cap (e.g., cap 902, 1002, 1102, 1402, 1502, 1602, 1702) is less than area of the light converter (e.g., light converter 904, 1004, 1404, 1504, 1604, 1704) adjacent to the substrate (e.g., substrate 908, 1008, 1408, 1508, 1608, 1708), and wherein the cap (e.g., cap 902, 1002, 1102, 1402, 1502, 1602, 1702) can comprise a reflective top surface.

In various embodiments, exemplary LED package (e.g., LED package 900, 1000, 1100, 1200, 1400, 1500, 1600, 1700) can further comprise a reflective layer on a top surface of the cap (e.g., cap 902, 1002, 1102, 1402, 1502, 1602, 1702) that can comprise the reflective top surface, opposite of the LED, configured to reflect light incident on the cap (e.g., cap 902, 1002, 1102, 1402, 1502, 1602, 1702) that is reflected back in a direction of the LED package (e.g., LED package 900, 1000, 1100, 1200, 1400, 1500, 1600, 1700). For instance, an exemplary reflective layer on a top surface of the cap (e.g., cap 902, 1002, 1102, 1402, 1502, 1602, 1702) can comprise one or more of a coating or a micro-reflector array on the top surface of the cap (e.g., cap 902, 1002, 1102, 1402, 1502, 1602, 1702) or another layer adjacent to the top surface of the cap (e.g., cap 902, 1002, 1102, 1402, 1502, 1602, 1702). In another non-limiting aspect, an exemplary cap (e.g., cap 902, 1002, 1102, 1402, 1502, 1602, 1702) can be at least partially embedded into the light converter (e.g., light converter 904, 1004, 1404, 1504, 1604, 1704), for example, as further described herein.

In still other non-limiting embodiments, an exemplary LED package (e.g., LED package 900, 1000, 1100, 1200, 1400, 1500, 1600, 1700) can comprise a light converter (e.g., light converter 904, 1004, 1404, 1504, 1604, 1704) surrounding an LED chip (e.g., LED chip 906, 1006, 1106, 1406, 1506, 1606, 1706) positioned over a substrate (e.g., substrate 908, 1008, 1408, 1508, 1608, 1708), wherein the LED chip (e.g., LED chip 906, 1006, 1106, 1406, 1506, 1606, 1706) can comprise an LED chip (e.g., LED chip 906, 1006, 1106, 1406, 1506, 1606, 1706) side surface that can be defined by a portion of a first plane, wherein the light converter (e.g., light converter 904, 1004, 1404, 1504, 1604, 1704) can comprise a light converter (e.g., light converter 904, 1004, 1404, 1504, 1604, 1704) outer side surface that can be defined by a portion of a second plane, and wherein the second plane intersects the first plane at an inclined angle.

Further nonlimiting embodiments of exemplary LED package (e.g., LED package 900, 1000, 1100, 1200, 1400, 1500, 1600, 1700) can comprise a structure (e.g., light converter structure 1560, 1660) of the light converter (e.g., light converter 904, 1004, 1404, 1504, 1604, 1704) located adjacent to the portion of the second plane configured to one or more of prevent contaminant absorption into a material of the light converter (e.g., light converter 904, 1004, 1404, 1504, 1604, 1704) or promote light escape from the light converter (e.g., light converter 904, 1004, 1404, 1504, 1604, 1704) to a surrounding environment, for example, as further described herein. In a non-limiting aspect of exemplary LED package (e.g., LED package 900, 1000, 1100, 1200, 1400, 1500, 1600, 1700) an exemplary structure (e.g., light converter structure 1560, 1660) of the light converter (e.g., light converter 904, 1004, 1404, 1504, 1604, 1704) can comprise a layer of one or more of a polymer coating, an atomic layer deposition, or an engineered structure. For instance, in another non-limiting aspect of exemplary LED package (e.g., LED package 900, 1000, 1100, 1200, 1400, 1500, 1600, 1700), and exemplary structure (e.g., light converter structure 1560) of the light converter (e.g., light converter 904, 1004, 1404, 1504, 1604, 1704) can comprise a barrier to air and moisture absorption. In yet another non-limiting aspect of exemplary LED package (e.g., LED package 900, 1000, 1100, 1200, 1400, 1500, 1600, 1700), an exemplary structure (e.g., light converter structure 1660) of the light converter (e.g., light converter 904, 1004, 1404, 1504, 1604, 1704) can comprise one or more of a polished surface, a roughened surface, or an optical coating configured to promote light escape to the surrounding environment.

Still further nonlimiting embodiments of exemplary LED package (e.g., LED package 900, 1000, 1100, 1200, 1400, 1500, 1600, 1700) can comprise a cap (e.g., cap 902, 1002, 1102, 1402, 1502, 1602, 1702) positioned adjacent to and in contact with the light converter (e.g., light converter 904, 1004, 1404, 1504, 1604, 1704) and characterized by continuous contact between the cap (e.g., cap 902, 1002, 1102, 1402, 1502, 1602, 1702) and a top surface of the light converter (e.g., light converter 904, 1004, 1404, 1504, 1604, 1704) across an entirety of a bottom surface of the cap, wherein area of the bottom surface of the cap (e.g., cap 902, 1002, 1102, 1402, 1502, 1602, 1702) is less than area of the light converter (e.g., light converter 904, 1004, 1404, 1504, 1604, 1704) adjacent to the substrate (e.g., substrate 908, 1008, 1408, 1508, 1608, 1708).

The above description includes non-limiting examples of the various embodiments. It is, of course, not possible to describe every conceivable combination of components or methodologies for purposes of describing the disclosed subject matter, and one skilled in the art may recognize that further combinations and permutations of the various embodiments are possible. The disclosed subject matter is intended to embrace all such alterations, modifications, and variations that fall within the spirit and scope of the appended claims.

With regard to the various functions performed by the above-described components, the terms (including a reference to a “means”) used to describe such components are intended to also include, unless otherwise indicated, any structure(s) which performs the specified function of the described component (e.g., a functional equivalent), even if not structurally equivalent to the disclosed structure. In addition, while a particular feature of the disclosed subject matter may have been disclosed with respect to only one of several implementations, such feature may be combined with one or more other features of the other implementations as may be desired and advantageous for any given or particular application.

The terms “exemplary” and/or “demonstrative” as used herein are intended to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent structures and techniques known to one skilled in the art. Furthermore, to the extent that the terms “includes,” “has,” “contains,” and other similar words are used in either the detailed description or the claims, such terms are intended to be inclusive-in a manner similar to the term “comprising” as an open transition word-without precluding any additional or other elements.

The term “or” as used herein is intended to mean an inclusive “or” rather than an exclusive “or.” For example, the phrase “A or B” is intended to include instances of A, B, and both A and B. Additionally, the articles “a” and “an” as used in this application and the appended claims should generally be construed to mean “one or more” unless either otherwise specified or clear from the context to be directed to a singular form.

The term “set” as employed herein excludes the empty set, i.e., the set with no elements therein. Thus, a “set” in the subject disclosure includes one or more elements or entities. Likewise, the term “group” as utilized herein refers to a collection of one or more entities.

The terms “first,” “second,” “third,” and so forth, as used in the claims, unless otherwise clear by context, is for clarity only and doesn't otherwise indicate or imply any order in time. For instance, “a first determination,” “a second determination,” and “a third determination,” does not indicate or imply that the first determination is to be made before the second determination, or vice versa, etc.

The description of illustrated embodiments of the subject disclosure as provided herein, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as one skilled in the art can recognize. In this regard, while the subject matter has been described herein in connection with various embodiments and corresponding drawings, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A light emitting diode (LED) package, comprising:
a light converter surrounding an LED chip positioned over a substrate, wherein the LED chip comprises an LED chip side surface that can be defined by a portion of a first plane, wherein the light converter comprises a light converter outer side surface that can be defined by a portion of a second plane, and wherein the second plane intersects the first plane at an inclined angle, wherein the light converter comprises a plurality of regions, and wherein each of the plurality of regions has a differing material composition from at least one other of the plurality of regions; and
a cap positioned adjacent to and in contact with the light converter and characterized by continuous contact between the cap and a top surface of the light converter across an entirety of a bottom surface of the cap, wherein area of the bottom surface of the cap is less than area of the light converter adjacent to the substrate.

2. The LED package of claim 1, wherein the LED chip comprises an indium gallium nitride (InGaN) type LED chip or an aluminum indium gallium phosphide (AlInGaP) type LED chip.

3. The LED package of claim 1, wherein the light converter comprises a mixture of resin and light conversion particles.

4. The LED package of claim 3, wherein the light conversion particles comprise at least one of nitride-based phosphor particles, beta-sialon-based phosphor particles, silicate particles, potassium fluorosilicate (KSF) particles, or quantum dot particles.

5. The LED package of claim 1, wherein the differing material composition differs in at least one of refractive index, light conversion efficiency sensitivity to temperature, or light diffusion level.

6. The LED package of claim 1, wherein the plurality of regions comprises at least three regions, which plurality of regions varies in the differing material composition according to the distance away from the LED chip and towards the cap.

7. The LED package of claim 1, further comprising:
a first region of the plurality of regions having a first material composition nearest the LED chip;
a second region of the plurality of regions having a second material composition; and
a third region of the plurality of regions having a third material composition nearest the cap.

8. The LED package of claim 7, wherein the first region has a highest refractive index and wherein the third region has a lowest refractive index.

9. The LED package of claim 7, wherein the first region has a lowest light conversion efficiency sensitivity to temperature and wherein the third region has a highest light conversion efficiency sensitivity to temperature.

10. The LED package of claim 7, wherein the first region has a highest light diffusion level and wherein the third region has a lowest light diffusion level.

11. The LED package of claim 10, wherein the highest light diffusion level and the lowest light diffusion level vary as a result of differing concentrations of light diffusing agents in the plurality of regions of the light converter, wherein the light scattering agents comprise at least one of silica (SiO₂) particles, titanium dioxide (TiO₂) particles, barium sulfate (BaSO₄) particles, or alumina (Al₂O₃) particles.

12. The LED package of claim 1, wherein the cap comprises a reflective top surface.

13. The LED package of claim 1, further comprising:
a reflective layer on a top surface of the cap, opposite of the LED chip, configured to reflect light incident on the cap that is reflected back in a direction of the LED package.

14. The LED package of claim 13, wherein the reflective layer on a top surface of the cap comprises at least one of a coating or a micro-reflector array on the top surface of the cap or another layer adjacent to the top surface of the cap and comprising at least one of a self-assembled micro-reflector array or an etched micro-reflector array.

15. The LED package of claim 1, wherein the cap is at least partially embedded into the light converter.

16. The LED package of claim 1, wherein the cap comprises a second plurality of regions, and wherein each of the plurality of regions has a different material composition from at least one other of the plurality of regions.

17. The LED package of claim 16, wherein the differing material composition differs in at least one of reflectivity or light diffusion level.

18. A light emitting diode (LED) package, comprising:
a light converter surrounding an LED chip positioned over a substrate, wherein the LED chip comprises an LED chip side surface that can be defined by a portion of a first plane, wherein the light converter comprises a light converter outer side surface that can be defined by a portion of a second plane, and wherein the second plane intersects the first plane at an inclined angle; and
a cap positioned adjacent to and in contact with the light converter and characterized by continuous contact between the cap and a top surface of the light converter across an entirety of a bottom surface of the cap, wherein area of the bottom surface of the cap is less than area of the light converter adjacent to the substrate, and wherein the cap comprises a reflective top surface.

19. The LED package of claim 18, further comprising:
a reflective layer on a top surface of the cap comprising the reflective top surface, opposite of the LED, configured to reflect light incident on the cap that is reflected back in a direction of the LED package.

20. The LED package of claim 19, wherein the reflective layer on a top surface of the cap comprises at least one of a coating or a micro-reflector array on the top surface of the cap or another layer adjacent to the top surface of the cap.

21. The LED package of claim 18, wherein the cap is at least partially embedded into the light converter.

22. A light emitting diode (LED) package, comprising:
a light converter surrounding an LED chip positioned over a substrate, wherein the LED chip comprises an LED chip side surface that can be defined by a portion of a first plane, wherein the light converter comprises a light converter outer side surface that can be defined by a portion of a second plane, and wherein the second plane intersects the first plane at an inclined angle;
a structure of the light converter located adjacent to the portion of the second plane configured to at least one of prevent contaminant absorption into a material of the light converter or promote light escape from the light converter to a surrounding environment; and
a cap positioned adjacent to and in contact with the light converter and characterized by continuous contact between the cap and a top surface of the light converter across an entirety of a bottom surface of the cap, wherein area of the bottom surface of the cap is less than area of the light converter adjacent to the substrate.

23. The LED package of claim 22, wherein the structure of the light converter comprises a layer of at least one of a polymer coating, an atomic layer deposition, or an engineered structure.

24. The LED package of claim 23, wherein the structure of the light converter comprises a barrier to air and moisture absorption.

25. The LED package of claim 23, wherein the structure of the light converter comprises at least one of a polished surface, a roughened surface, or an optical coating configured to promote light escape to the surrounding environment.
